(19) United States
(12) Patent Application Publication
(10) Pub. No.: US 2016/0268291 A1
(43) Pub. Date: Sep. 15, 2016

(54) SEMICONDUCTOR DEVICE AND MANUFACTURING METHOD OF SEMICONDUCTOR DEVICE

(71) Applicant: Kabushiki Kaisha Toshiba, Minato-ku (JP)

(72) Inventor: Munio ISHIMURA, Suzuka (JP)

(73) Assignee: Kabushiki Kaisha Toshiba, Minato-ku (JP)

(21) Appl. No.: 14/816,420

(22) Filed: Aug. 3, 2015

Related U.S. Application Data
(60) Provisional application No. 62/132,846, filed on Mar. 13, 2015.

(51) Int. Cl. H01L 27/115; H01L 21/768

(52) U.S. Cl. CPC H01L 27/11582; H01L 21/76883; H01L 21/76816

(57) ABSTRACT

According to one embodiment, a stacked body of N layers is stacked on a semiconductor substrate, steps are provided in the stacked body such that upper layers are retracted behind lower layers, N lower openings are provided in correspondence with the individual layers of the stacked body and are equal in depth, one to N upper openings are provided on one to N lower openings and are different in depth, N lower-layer contact electrodes are provided in the lower openings, and one to N upper-layer contact electrodes are provided in the upper openings.

### CROSS-REFERENCE TO RELATED APPLICATIONS

This application is based upon and claims the benefit of priority from U.S. Provisional Application No. 62/132,846, filed on Mar. 13, 2015; the entire contents of which are incorporated herein by reference.

### FIELD

Embodiments described herein relate generally to a semiconductor device and a manufacturing method of a semiconductor device.

### BACKGROUND

With an increase in density, semiconductor devices have been structured three-dimensionally. In structuring such a semiconductor device, when contacts are provided at a stepped portion, the contacts may be different in depth.

### BRIEF DESCRIPTION OF THE DRAWINGS

FIGS. 1A and 1B are cross-sectional views illustrating a forming method of contacts applied to a semiconductor device according to a first embodiment;

FIGS. 2A and 2B are cross-sectional views illustrating the forming method of contacts applied to the semiconductor device according to the first embodiment;

FIGS. 3A and 3B are cross-sectional views illustrating the forming method of contacts applied to the semiconductor device according to the first embodiment;

FIGS. 4A and 4B are cross-sectional views illustrating the forming method of contacts applied to the semiconductor device according to the first embodiment;

FIGS. 5A and 5B are cross-sectional views illustrating the forming method of contacts applied to the semiconductor device according to the first embodiment;

FIGS. 6A and 6B are cross-sectional views illustrating the forming method of contacts applied t the semiconductor device according to the first embodiment;

FIGS. 7A and 7B are cross-sectional views illustrating a forming method of contacts applied to a semiconductor device according to a second embodiment;

FIGS. 8A and 8B are cross-sectional views illustrating the forming method of contacts applied to the semiconductor devise according to the second embodiment;

FIGS. 9A and 98 are cross-sectional views illustrating the forming method of contacts applied to the semiconductor device according to the second embodiment;

FIGS. 10A and 10B are cross-sectional views illustrating a forming method of contacts applied to a semiconductor device according to a third embodiment;

FIGS. 11A and 118 are cross-sectional views illustrating the forming method of contacts applied to the semiconductor device according to the third embodiment;

FIGS. 12A and 12B are cross-sectional views illustrating a forming method of contacts applied to a semiconductor device according to a fourth embodiment;

FIGS. 13A and 13B are cross-sectional views illustrating a forming method of contacts applied to a semiconductor device according to a fifth embodiment;

FIGS. 14A and 14B are cross-sectional views illustrating the forming method of contacts applied to the semiconductor device according to the fifth embodiment;

FIG. 15 is a schematic perspective view of a memory cell array in a non-volatile semiconductor of race device according to a cloth embodiment; and

FIG. 16A is a schematic cross-sectional view of the non-volatile semiconductor storage device according to the sixth embodiment, and FIG. 168 is an enlarged cross-sectional view of memory cells illustrated in FIG. 16A.

### DETAILED DESCRIPTION

In general, according to one embodiment, a semiconductor device includes a stacked body of N (N is an integer of 2 or more) layers, steps, N lower openings, one to N upper openings, N lower-layer contact electrodes, and one to N upper-layer contact electrodes. The stacked body of the N layers is stacked on a semiconductor substrate. The steps are formed in the stacked body such that upper layers are retracted behind lower layers. The N lower openings are provided in correspondence with the individual layers of the stacked body and are equal in depth. The one to N upper openings are provided on the one to N lower openings and are different in depth. The N lower-layer contact electrodes are provided in the lower openings. The one to N upper-layer contact electrodes are provided in the upper openings.

Exemplary embodiments of a semiconductor device and a manufacturing method of a semiconductor device will be explained below in detail with reference to the accompanying drawings. The present invention is not limited to the following embodiments.

### First Embodiment

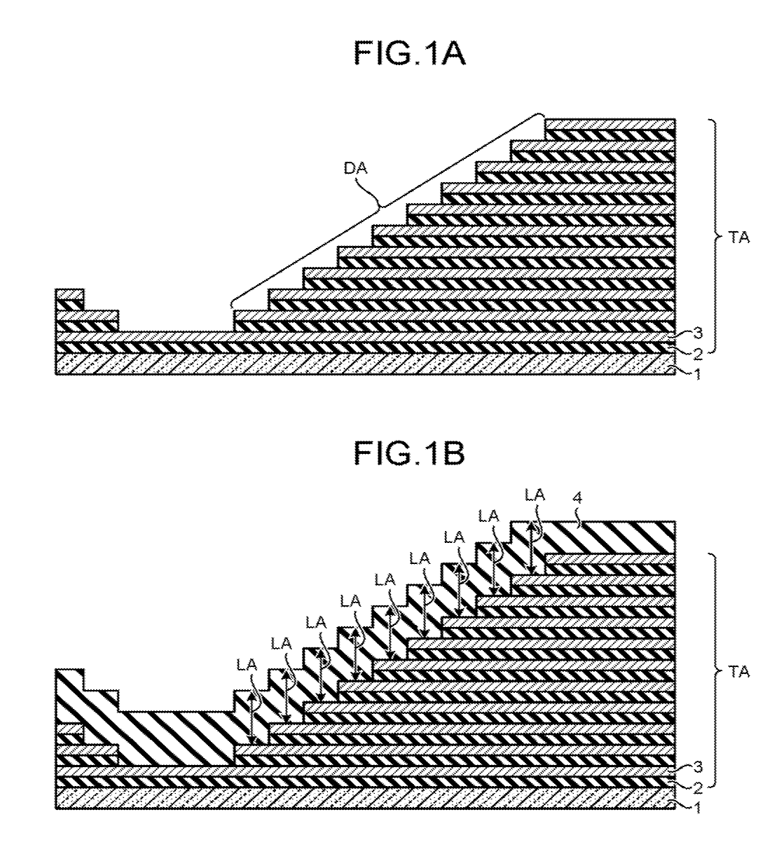

FIGS. 1A to 6A and 1B to 6B are cross-sectional views illustrating a forming method of contacts applied to a semiconductor device according to a first embodiment.

Referring to FIG. 1A, a stacked body TA is formed on a foundation layer 1. The foundation layer 1 may be a semiconductor substrate, an insulator, or an electric conductor. An integrated circuit may be formed on the foundation layer 1. Each of layers in the stacked body TA is provided with an insulating layer 2 and a conductive layer 3. The insulating layers 2 and the conductive layers 3 are alternately stacked to form the stacked body TA. FIG. 1A illustrates the configuration of the stacked body TA in which 11 insulating layers 2 and 11 conductive layers 3 are alternately stacked. The layers in the stacked body TA may be equal in film thickness. The material for the insulating layers 2 may be SiO₂ or the like, for example. The insulating layers 2 may be etch stopper layers. The material for the conductive layers 3 may be an impurity-added polysilicon or a metal such as W or Cu. The conductive layers 3 may be ion-implanted layers. The conductive layers 3 may be used as word lines for an NAND flash memory, for example. The stacked body TA has steps DA therein. The steps DA may be formed such that upper layers are retracted behind lower layers in the stacked body TA.

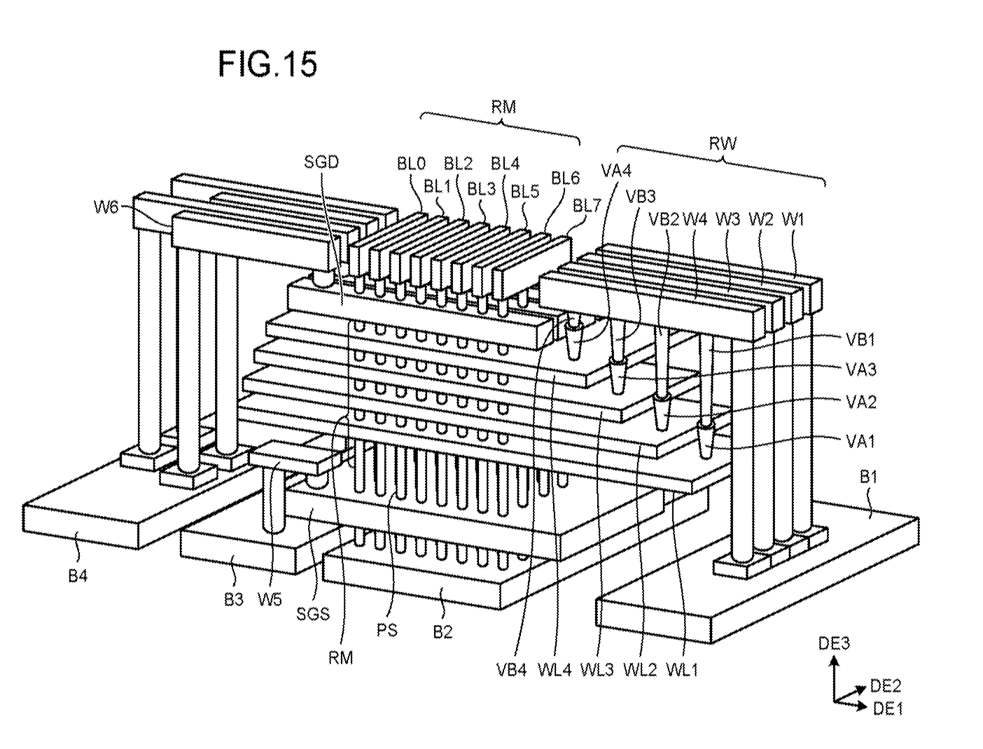

Next, as illustrated in FIG. 15, an insulating layer 4 is formed on the steps DA in the stacked body TA by a method such as CVD. At that time, the insulating layer 4 may be equal in film thickness LA on the steps DA in the stacked body TA. Film formation conditions for the insulating layer 4 may be set such that the insulating layer 4 has favorable step coverage. The film formation conditions may include the kind of a material gas, the flow rate of the gas, film formation temperature, film formation pressure, and the like, for example.

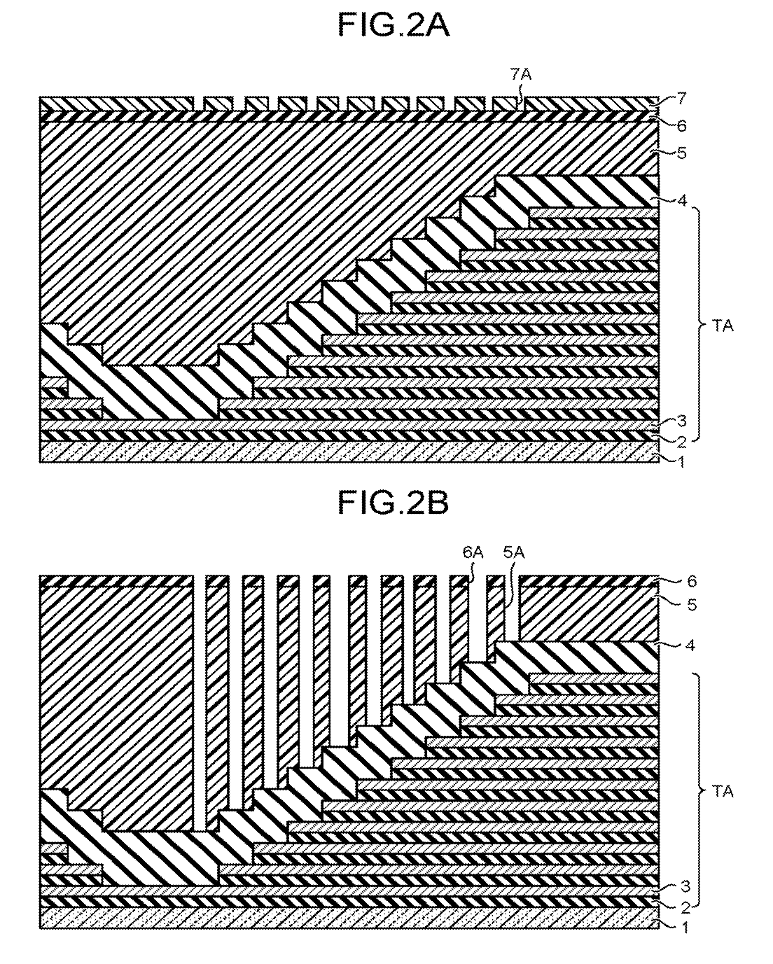

Next, as illustrated in FIG. 2A, a resist film is formed on the insulating layer 4 so as to be embedded in the steps DA by a method such as spin coating. Then, a hard mask film 6 is formed on the resist film 5 by a method such as CVD. The material for the hard mask film 6 may be SiO₂, for example. Then, a resist film 7 is formed on the hard mask film 6 by a method such as spin coating. Then, openings 7A are formed in the resist film 7 by a photolithographic technique. At that time, the openings 7A may be arranged corresponding to each of the steps DA.

Next, as illustrated in FIG. 2B, the hard mask film 6 is etched via the openings 7A to form openings 6A in the hard mask film 6. Further, the resist film 5 is etched via the openings 6A to form openings 5A in the resist film 5.

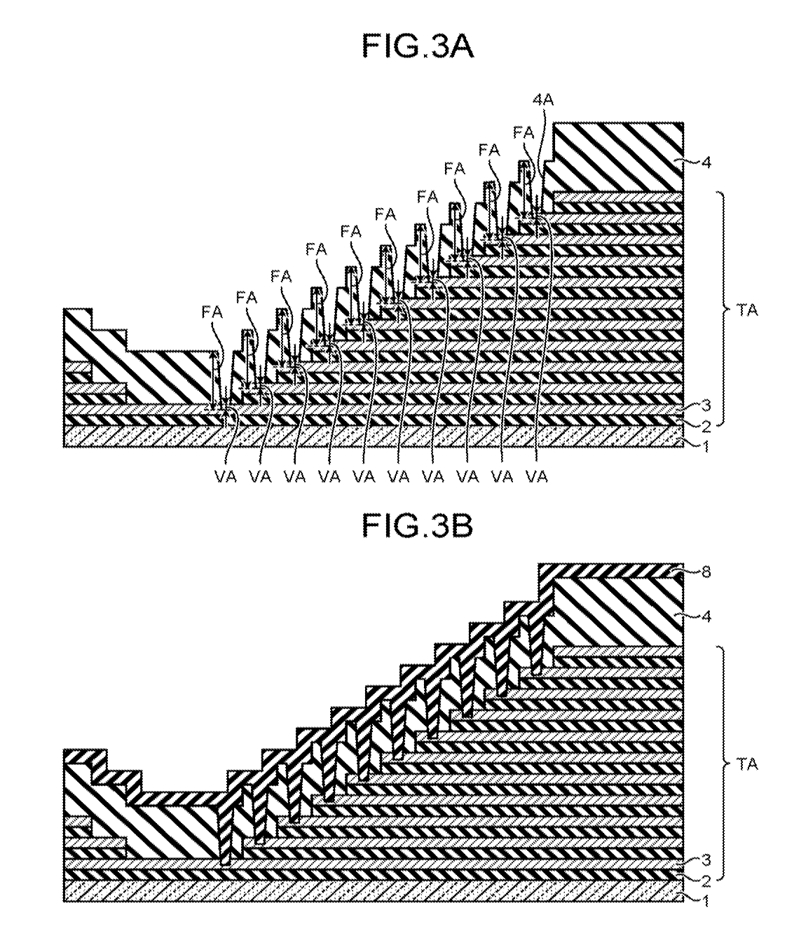

Next, as illustrated in FIG. 3A, the insulating layer 4 is etched via the openings 5A to form openings 4A in the insulating layer 4. At that time, the conductive layers 3 may be exposed to the outside via the openings 4A. The openings 4A may be equal in depth FA between the steps DA. By making the insulating layer 4 on the steps DA equal in film thickness LA, the conductive layers 3 can be equal in over-etching amount VA between the steps DA. At that time, the depths FA of the openings 4A can be expressed by LA+VA.

Next, as illustrated in FIG. 3B, a sacrifice layer 8 is formed on the insulating layer 4 so as to be embedded in the openings 4A by a method such as CVD. The material for the sacrifice layer 5 may be lower in etching resistance than that for the insulating layer 4. For example, the material for the sacrifice layer 8 may be an amorphous silicon, polysilicon, SiN, or the like, for example.

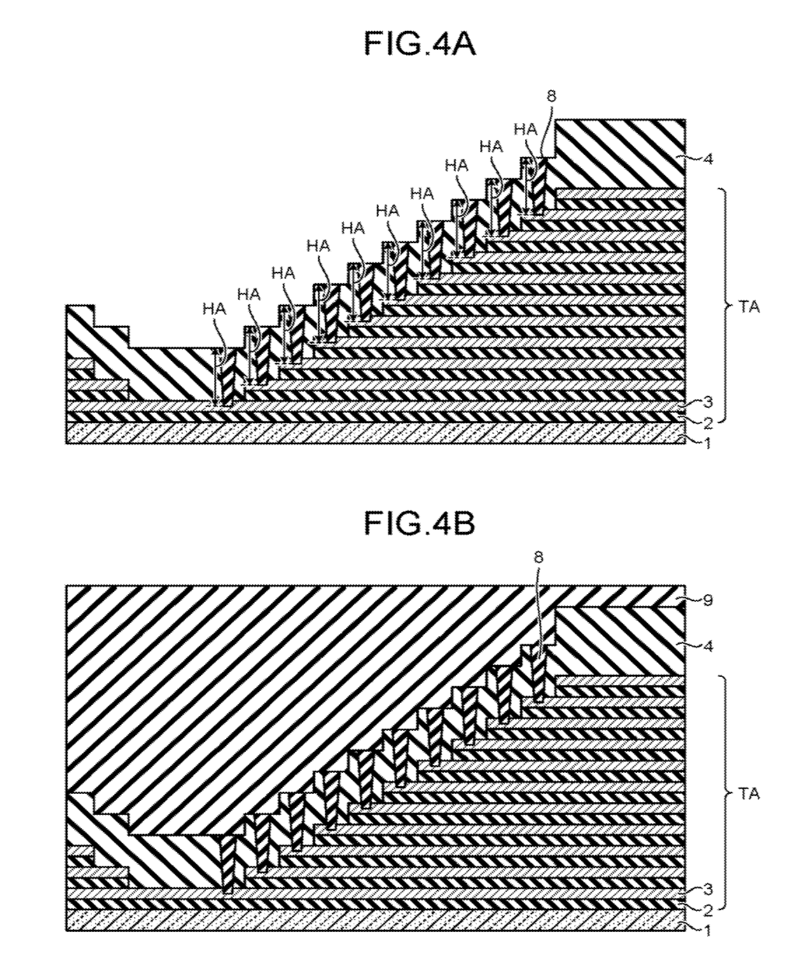

Next, as illustrated in FIG. 4A, the sacrifice layer 8 is thinned by isotropic etching to expose the surface of the insulating layer 4 to the outside with the sacrifice layer 8 left in the openings 4A. At that time, the sacrifice layer 8 on the steps DA may be equal in height HA. At that time, the relationship HA=FA can be met.

Next, as illustrated in FIG. 4B, an insulating layer 9 is deposited on the sacrifice layer 8 so as to be embedded in the steps DA by a method such as CVD. Then, the insulating layer 9 is thinned by a method such as CMP to flatten out the surface of the insulating layer 9. The sacrifice layer 8 may remain embedded in the insulating layer 9 on the steps DA. At that time, the insulating layer 9 may be different in film thickness between the steps DA in the stacked body TA.

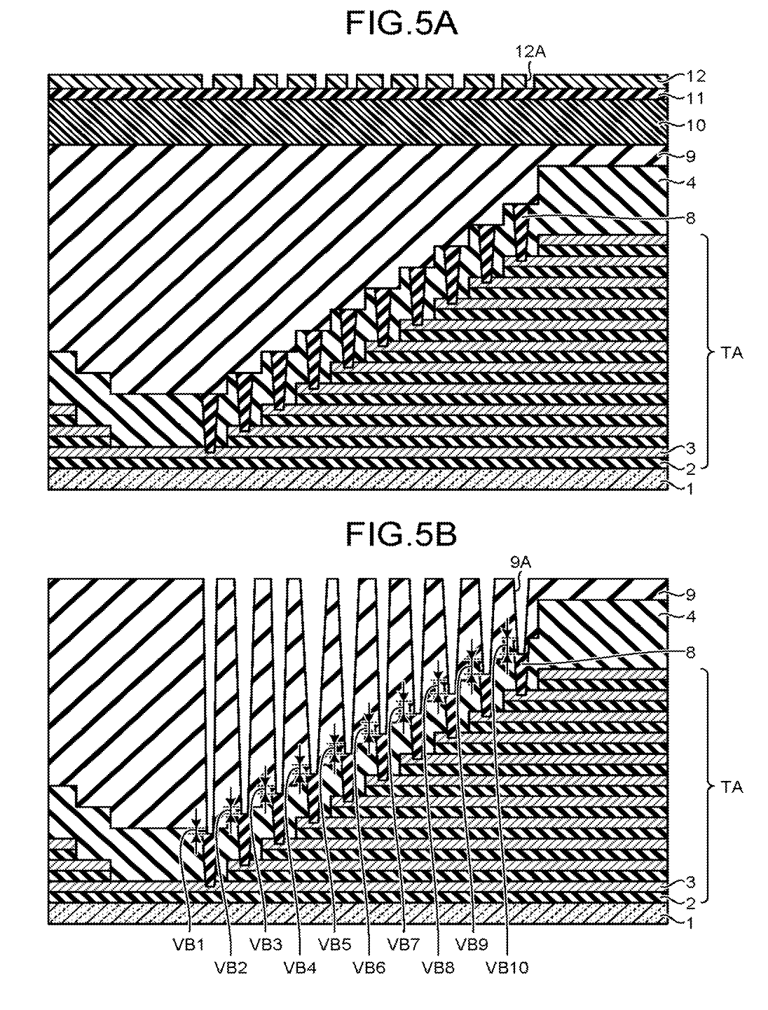

Next, as illustrated in FIG. 5A, a resist film 10 is formed on the insulating layer 9 by a method such as spin coating. Then, a hard mask film 11 is formed on the resist film 10 by a method such as CVD. The material for the hard mask film 11 may be SiO₂, for example. Then, a resist film 12 is formed on the hard mask film 11 by a method such as spin coating. Then, openings 12A are formed in the resist film 12 by a photolithographic technique. At that time, the openings 12A may be arranged corresponding to the sacrifice layer 8 in the steps DA.

Next, as illustrated in FIG. 5B, the hard mask film 11 is etched via the openings 12A to form openings in the hard mask film 11. Further, the resist film 10 is etched via the openings in the hard mask film 11 to form openings in the resist film 10. Moreover, the insulating layer 9 is etched via the openings in the resist film 10 to form openings 9A in the insulating layer 9. At that time, the sacrifice layer 8 may be exposed to the outside via the openings 9A. The film thickness of the insulating layer 9 on the steps DA is larger in the lower layers than in the upper layers. Accordingly, the time of etching the sacrifice layer 8 in the steps DA is longer in the upper layers than in the lower layers, and over-etching amounts VB1 to VB10 of the sacrifice layer 8 in the steps DA are larger in the upper layers than in the lower layers. By embedding the sacrifice layer 8 in the opening 4A before formation of the openings 9A in the insulating layer 9, the over-etching in the insulating layer 9 can be absorbed in the sacrifice layer 8. Therefore, it is possible to prevent the conductive layers 3 from being over-etched at the formation of the openings 9A in the insulating layer 9, and when the conductive layers 3 are thinned, it is possible to prevent the conductive layers 3 from being penetrated. This makes it possible to prevent occurrence of insulation failure between the layers in the stacked body TA while supporting the multi-layer structure of the stacked body TA.

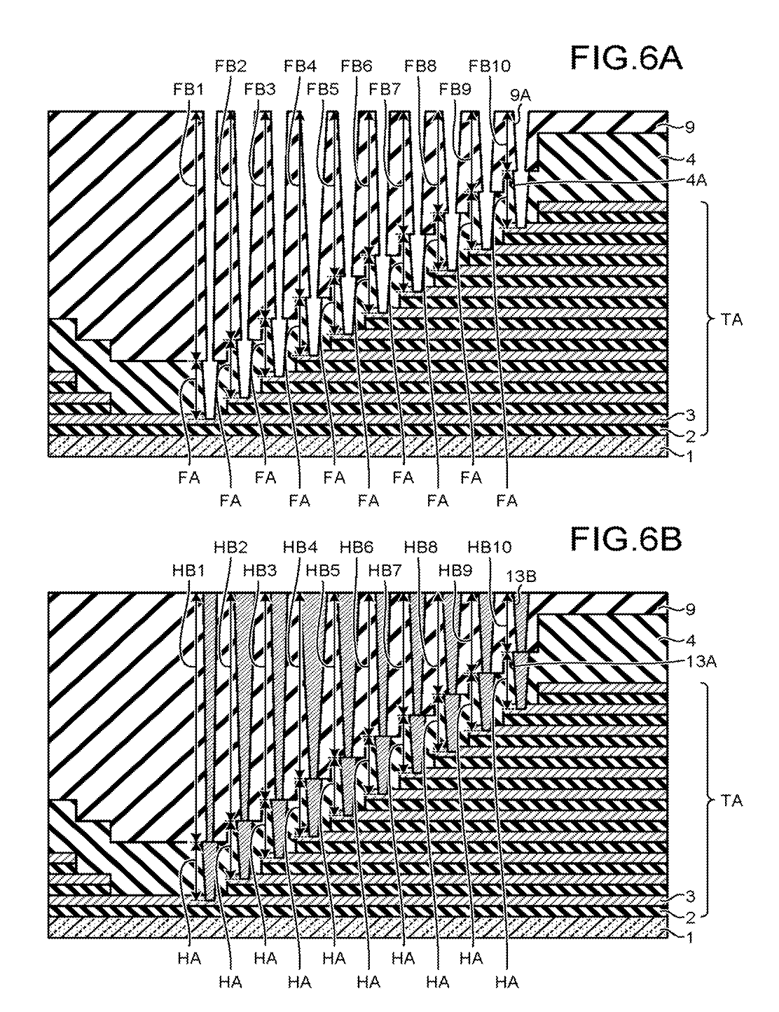

Next, as illustrated in FIG. 6A, the sacrifice layer 8 is removed from the openings 4A. At that time, the openings 9A can be arranged on the openings 4A in the individual layers. Depths FB1 to FB10 of the openings 9A may be different from each other between the steps DA.

Next, as illustrated in FIG. 6B, electric conductors are embedded in the openings 4A and 9A by a method such as sputtering or CVD to form contact plugs 13A in the openings 4A and form contact plugs 13B in the openings 9A. The material for the contact plugs 13A may be an impurity-added polysilicon or a metal such as W or Cu, for example. The contact plugs 13A may be equal in height HA. At that time, the contact plugs 13A may dig into the conductive layers 3 by the over-etching amount VA. Therefore, the contact plugs 13A can be equal in depth of digging into the conductive layers 3. Lengths HB1 to HB10 of the contact plugs 13B may be different from each other. The lengths HB1 to HB10 of the contact plugs 135 may be set such that the top surfaces of the contact plugs 13B are equal in length. The top surfaces of the contact plugs 13A may be larger in area than the bottom surfaces of the contact plugs 13B.

In the foregoing embodiment, the stacked body TA has a stepped structure of 10 steps. Alternatively, the stacked body TA may have a stepped structure of N (N is an integer of 2 or more) steps. The stepped structure may not necessarily a stacked body of conductive layers and insulating layers, but may be an ion-implanted structure or a structure into which stopper layers are inserted.

### Second Embodiment

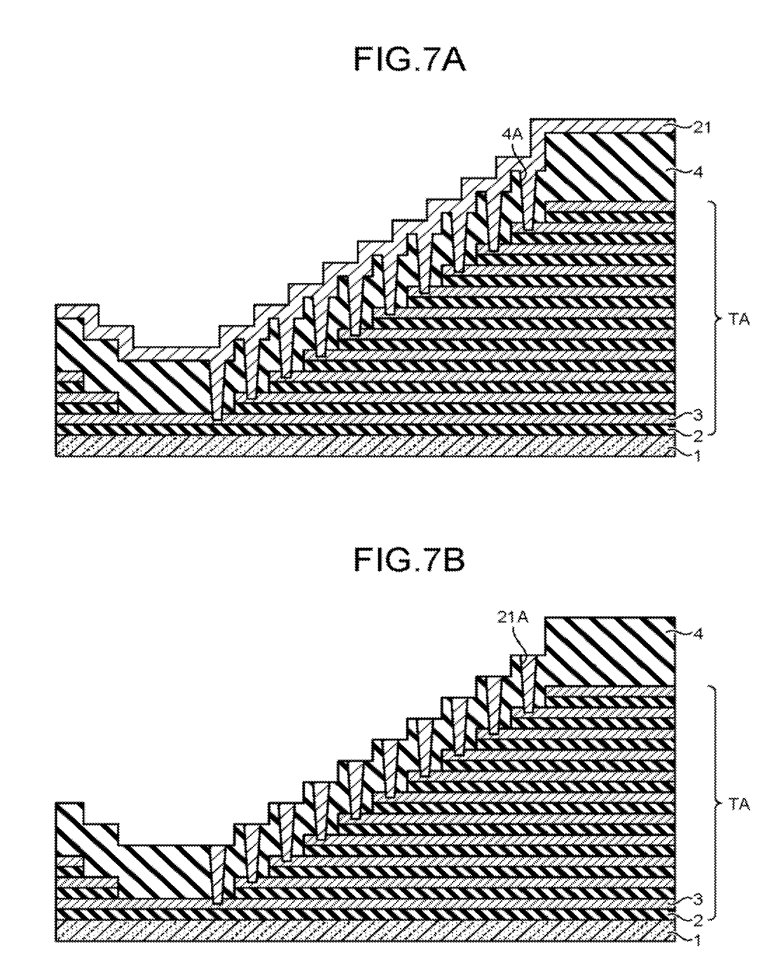

FIGS. 7A to 9A and 7B to 9B are cross-sectional views illustrating a forming method of contacts applied to a semiconductor device according to a second embodiment.

In the first embodiment, the sacrifice layer 8 is embedded into the openings 4A in the process of FIG. 3B. In the second embodiment, a conductive film 21 is embedded in the openings 4A as illustrated in FIG. 7A. The material for the conductive film 21 may be an impurity-added polysilicon, or a metal such as W or Cu, for example. In the other respects, the second embodiment is the same as the first embodiment.

Specifically, as illustrated in FIG. 7B, the conductive film 21 is thinned by isotropic etching to form contact plugs 21A in the openings 4A and expose the surface of the insulating layer 4 to the outside.

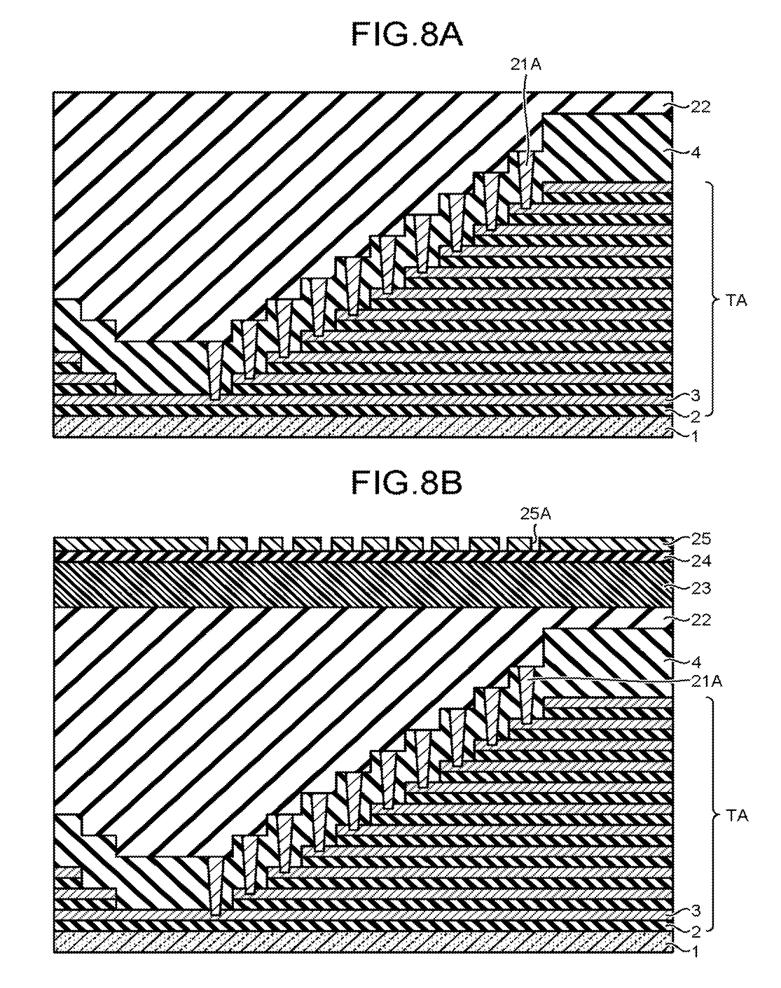

Next, as illustrated in FIG. 8A, an insulating layer 22 is deposited on the contact plugs 21A so as to be embedded in the steps DA by a method such as CVD. Then, the insulating layer 22 is thinned by a method such as CMP to flatten out the surface of the insulating layer 22. The contact plugs 21A may remain embedded in the insulating layer 22 on the individual layers of the steps DA. At that time, the film thickness of the insulating layer 22 may be different between the steps DA in the stacked body TA.

Next, as illustrated in FIG. 8B, a resist film 23 is formed on the insulating layer 22 by a method such as spin coating. Then, a hard mask film 24 is formed on the resist film 23 by a method such as CVD. Then, a resist film 25 is formed on the hard mask film 24 by a method such as spin coating. Then, openings 25A are formed in the resist film 25 by a photolithographic technique. At that time, the openings 25A may be arranged on the contact plugs 21A in the individual layers of the steps DA.

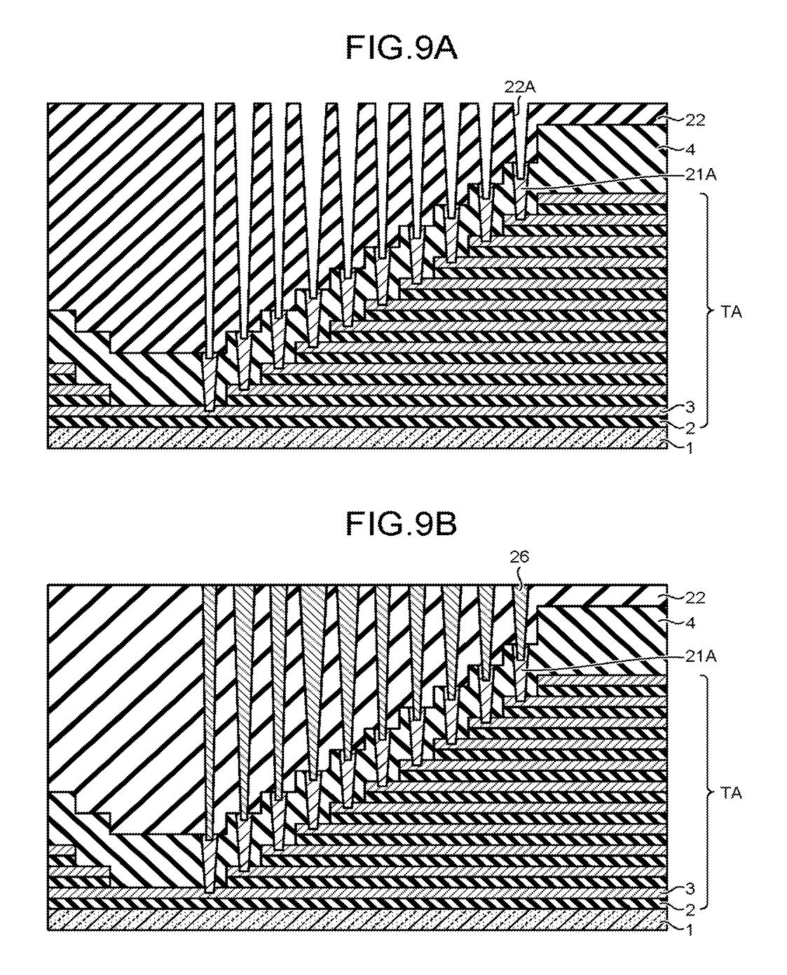

Next, as illustrated in FIG. 9A, the hard mask film 24 is etched via the openings 25A to form openings in the hard mask film 24. Further, the resist film 23 is etched via the openings in the hard mask film 24 to form openings in the resist film 23. Moreover, the insulating layer 22 is etched via the openings in the resist film 23 to form openings 22A in the insulating layer 22. At that time, the contact plugs 21A may be exposed to the outside via the openings 22A. The film thickness of the insulating layer 22 on the steps DA is larger in the lower layers than in the upper layers. Accordingly, the time of etching the contact plugs 21A in the steps DA is longer in the upper layers than in the lower layers, and over-etching amounts of the contact plugs 21A in the steps DA are larger in the upper layers than in the lower layers. By embedding the contact plugs 21A in the opening 4A before formation of the openings 22A in the insulating layer 22, the over-etching in the insulating layer 22 can be absorbed in the contact plugs 21A. Therefore, it is possible to prevent the conductive layers 3 from being over-etched at the formation of the openings 22A in the insulating layer 22, and when the conductive layers 3 are thinned, it is possible to prevent the conductive layers 3 from being penetrated. This makes it possible to prevent occurrence of insulation failure between the layers in the stacked body TA while supporting the multi-layer structure of the stacked body TA. Since the over-etching amounts of the contact plugs 21A are larger in the upper layers than in the lower layers, the lengths of the contact plugs 21A are lower in the upper layers than the lower layers.

Next, as illustrated in FIG. 9B, electric conductors are embedded in the openings 22A by a method such as sputtering or CVD to form contact plugs 26 in the openings 22A. The material for the contact plugs 26 may be an impurity-added polysilicon or a metal such as b or Cu, for example. The contact plugs 26 may be different in length. Lengths of the contact plugs 26 may be set such that the top surfaces of the contact plugs 26 are equal in length. The top surfaces of the contact plugs 21A may be larger in area than the bottom surfaces of the contact plugs 26. At that time, the contact plugs 26 may dig into the contact plugs 21A. The depth of digging may be larger in the upper layers than in the lower layers of the steps DA.

By embedding the contact plugs 21A into the openings 4A before the formation of the openings 22A, it is not necessary to remove the contact plugs 21A before embedding the contact plugs 26 into the openings 22A, thereby reducing the number of processes. In addition, the contact plugs 21A can be used as stopper layers at the formation of the openings 22A to improve the stopper layers in etching resistance.

### Third Embodiment

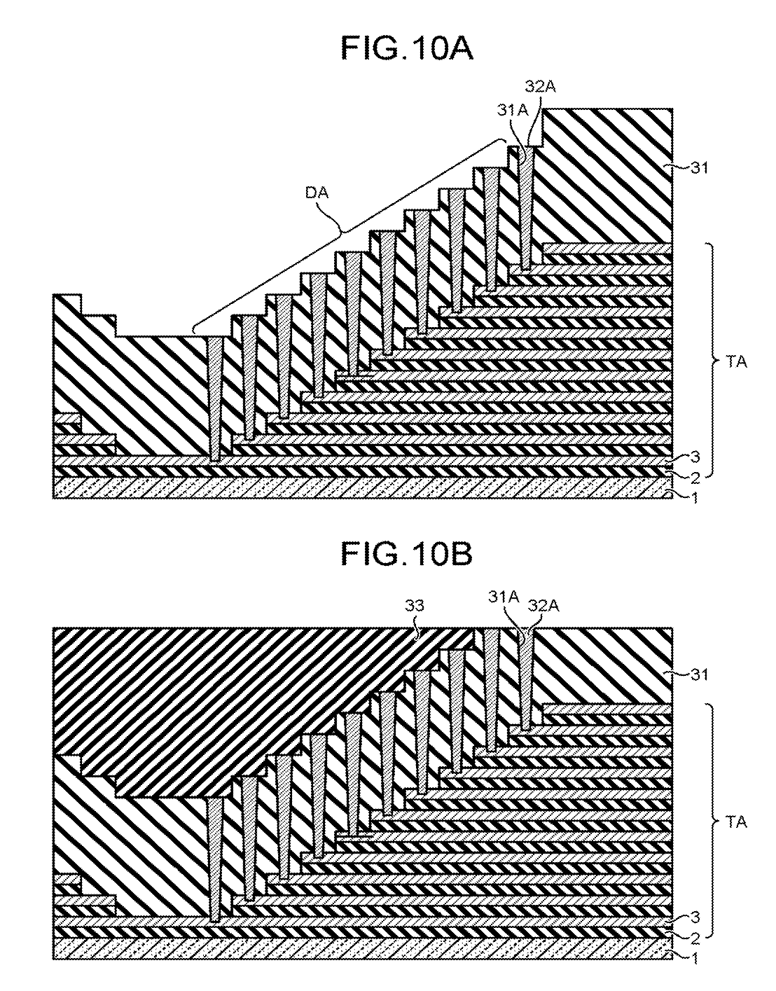

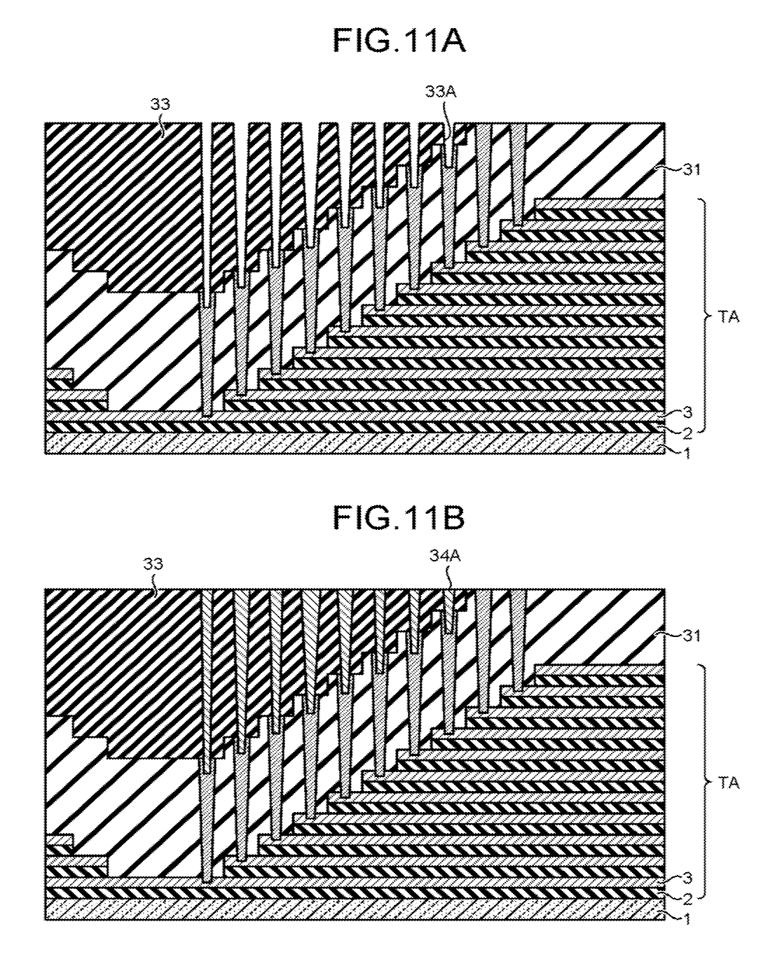

FIGS. 10A, 11A, 10B, and 11B are cross-sectional views illustrating a forming method of contacts applied to a semiconductor device according a third embodiment. In the third embodiment, contact plugs are formed in lower openings. However, this method is also applicable to the case of forming a sacrifice film in the lower openings.

In the step of FIG. 10A, an insulating layer 31 is formed instead of the insulating layer 4 illustrated in FIG. 7B. Openings 31A are formed in the insulating layer 31, and contact plugs 32A are embedded in the openings 31A. At that time, the film thickness of the insulating layer 31 may be set such that top surfaces of the contact plugs 32A in the upper layers of the stacked body TA protrude from the stacked body TA.

Next, as illustrated in FIG. 10B, an insulating layer 33 is deposited on the insulating layer 31 and the contact plugs 32A so as to be embedded in the steps DA by a method such as CVD. Then, the insulating layers 31 and 33 are thinned by a method such as CMP to flatten out the surfaces of the insulating layers 31 and 33 and expose the surface of the insulating layer 31 to the outside. At that time, the top surfaces of the contact plugs 32A in the upper layers of the steps DA may be flush with the surface of the insulating layer 33.

Next, as illustrated in FIG. 11A, openings 33A are formed in the insulating layer 33 by the use of a lithographic technique or an etching technique. At that time, the contact plugs 32A in the lower layers of the steps DA may be exposed to the outside via the openings 33A.

Next, as illustrated in FIG. 11B, electric conductors are embedded in the openings 33A by a method such as sputtering or CVD to form contact plugs 34A in the openings 33A.

Accordingly, in the upper layers of the steps DA, after the formation of the contact plugs 32A of the same length, the top surfaces of the contact plugs 32A can be unified in length by a method such as CMP. This makes it possible to even out over-etching in the conductive layers 3 in the upper layers of the steps DA without having a multilayer structure. Meanwhile, in the lower layers of the steps DA, after the formation of the openings 31A of the same depth, the openings 33A different in depth can be formed. This makes it possible to form the openings in the lower layers of the steps DA so as to have a multilayer structure and even out over-etching in the conductive layers 3.

In the foregoing embodiment, the openings 33A are not formed in the two upper steps. Alternatively, the openings 33A may not be formed in the N or less upper steps.

### Fourth Embodiment

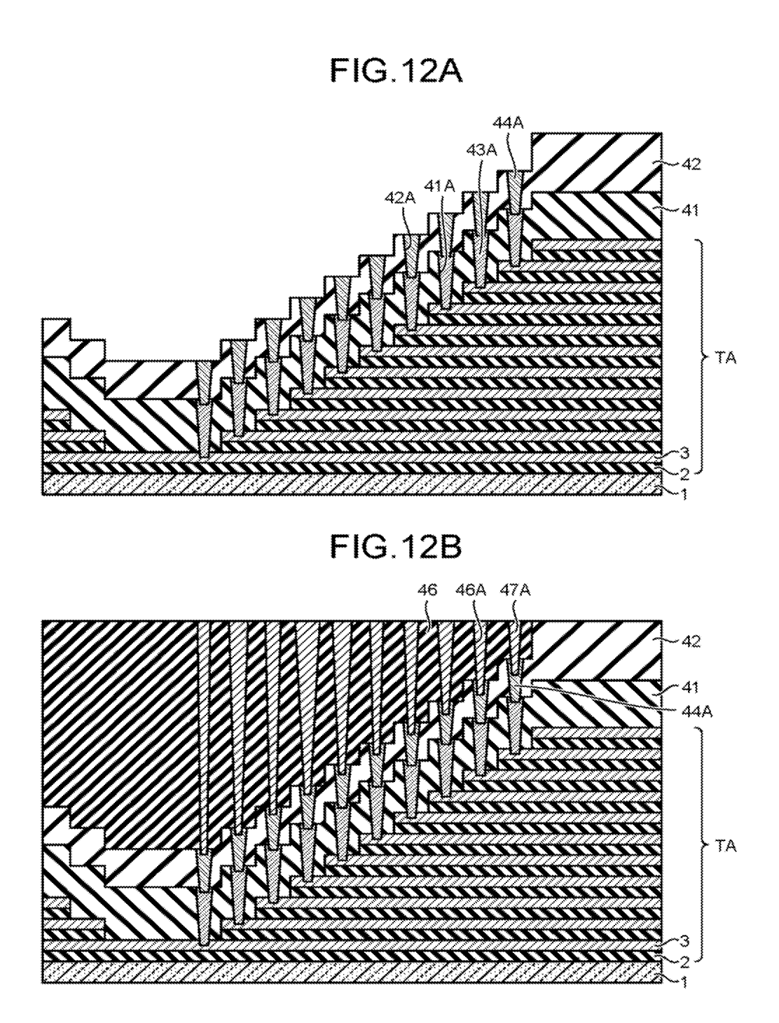

FIGS. 12A and 12B are cross-sectional views illustrating a forming method of contacts applied to a semiconductor device according to a fourth embodiment. In the fourth embodiment, contact plugs are formed in lower openings. However, this method is also applicable to the case of forming a sacrifice film in the lower openings. In the second embodiment, the openings have a two-layer structure. In the fourth embodiment, the openings have a three-layer structure. In the other respects, the fourth embodiment is the same as the second embodiment.

Specifically, as illustrated in FIG. 12A, insulating layers 41 and 42 are provided instead of the insulating layer 4 illustrated in FIG. 7B. The insulating layers 41 and 42 are formed in sequence on the steps DA in the stacked body TA. At that time, the insulating layer 41 on the steps DA in the stacked body TA may be equal in film thickness. In addition, the insulating layer 42 on the steps DA in the stacked body TA may be equal in film thickness. Openings 41A are formed in the insulating layer 41 corresponding to the individual steps DA, and openings 42A are formed in the insulating layer 42 corresponding to the individual steps DA. Contact plugs 43A are embedded in the openings 41A, and contact plugs 44A are embedded in the openings 42A.

Next, as illustrated in FIG. 12E, an insulating layer 46 is deposited on the contact plugs 44A so as to be embedded in the steps DA by a method such as CVD. Then, the insulating layer 46 is thinned by a method such as CMP to flatten out the surface of the insulating layer 46. Then, openings 46A are formed in the insulating layer 46 by the use of a lithographic technique or an etching technique. Next, electric conductors are embedded in the openings 46A by a method such as sputtering or CVD to form contact plugs 47A in the openings 46A.

In this example, increasing the number of stacks in the openings of the same depth makes it possible to decrease the maximum depth in the openings different in depth, and reduce over-etching amounts in the openings different in depth. In the foregoing embodiment, the number of stacks in the openings of the same depth is two. Alternatively, the number of stacks in the openings of the same depth may be M (M is an integer of 2 or more).

### Fifth Embodiment

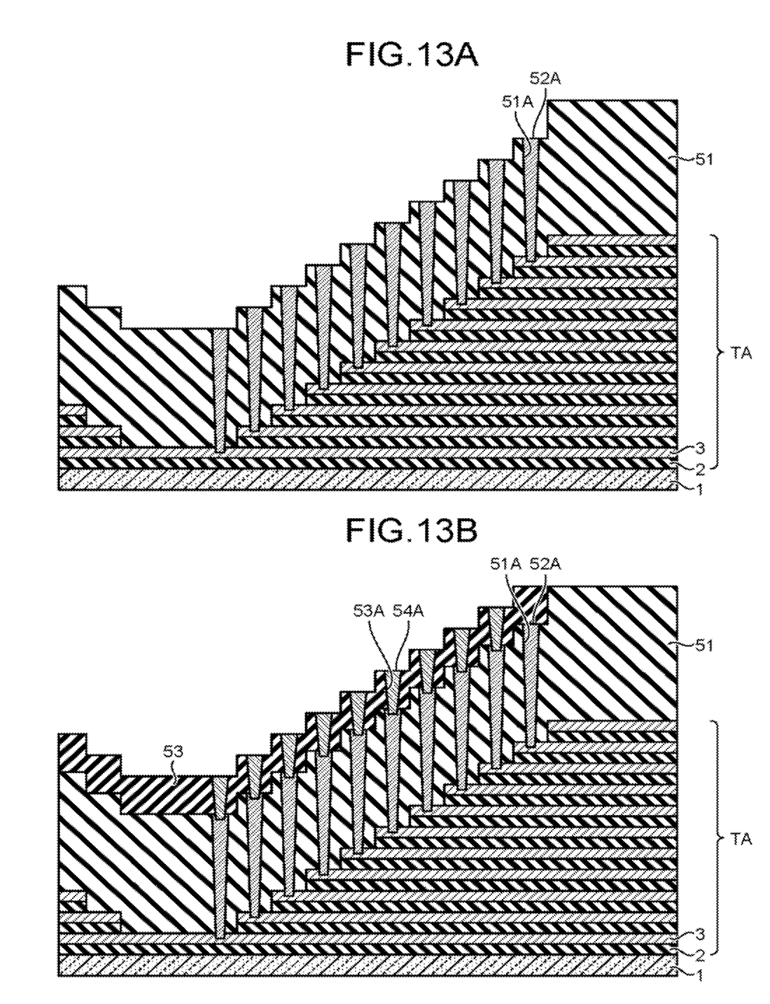

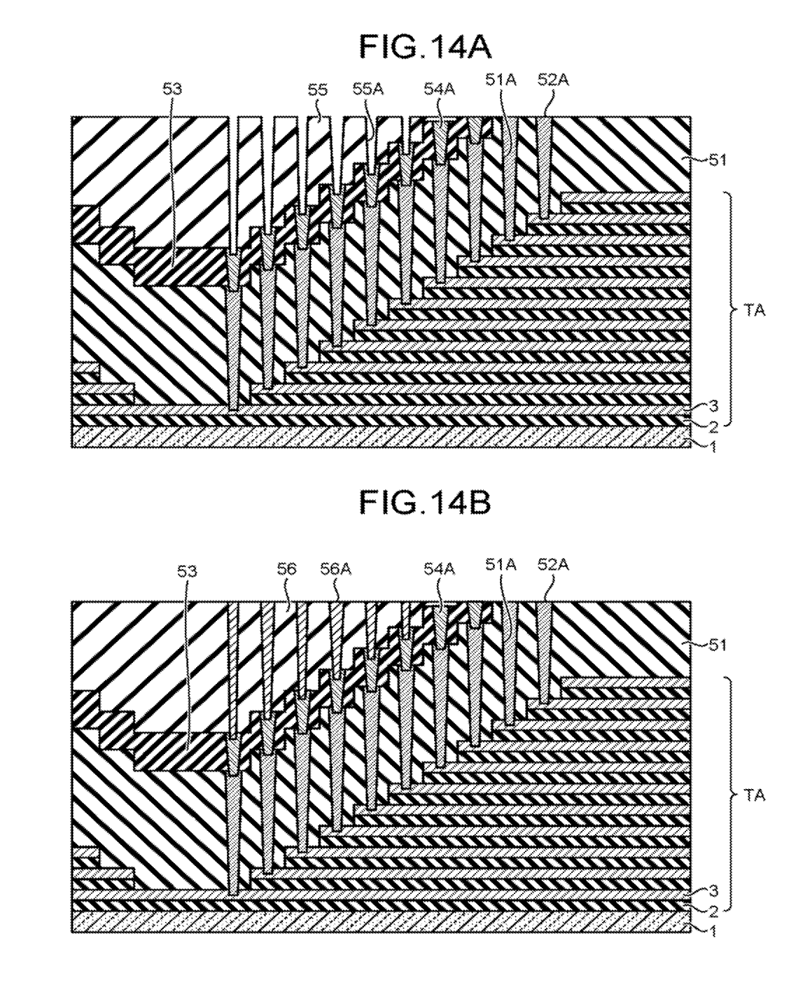

FIGS. 13A, 14A, 13B, and 14B are cross-sectional views illustrating a forming method of contacts applied to a semiconductor device according to a fifth embodiment. In the fifth embodiment, contact plugs are formed in lower openings. However, this method is also applicable to the case of forming a sacrifice film in the lower openings. In the third embodiment, the openings in the upper layers have a one-layer structure, and the openings in the lower layers have a two-layer structure. In the fifth embodiment, the openings in the upper layers have a one-layer structure, the openings in the intermediate layers have a two-layer structure, and the openings in the lower layers have a three-layer structure. In the other respects, the fifth embodiment is the same as the third embodiment.

Specifically, referring to FIG. 13A, an insulating layer 51 is formed instead of the insulating layer 31 illustrated in FIG. 10A. Openings 51A are formed in the insulating layer 51, and contact plugs 52A are embedded in the openings 51A. At that time, the insulating layer 51 on the steps DA in the stacked body TA may be equal in film thickness.

Next, as illustrated in FIG. 13B, an insulating layer 53 is formed on insulating layer 51 along the steps DA by a met hod such as CVD. The insulating layer 53 on the steps DA in the stacked body TA may be equal in film thickness. Then, openings 53A are formed in the insulating layer 53 in the steps DA of the lower and intermediate layers, and contact plugs 54A are embedded in the openings 53A.

Next, as illustrated in FIG. 14A, an insulating layer 55 is deposited on the insulating layer 53 and the contact plugs 54A so as to be embedded in the steps DA by a method such as CVD. Then, the insulating layers 51, 53, and 55 are thinned by a method such as CMP to flatten out the surfaces of the insulating layers 51, 53, and 55 and expose the surface of the insulating layers 51 and 53 to the outside. At that time, the top surfaces of the contact plugs 52A in the upper layers of the steps DA may be flush with the surface of the insulating layer 55. The top surfaces of the contact plugs 54A in the intermediate layers of the steps DA may be flush with the surface of the insulating layer 55.

Then, openings 55A are formed in the insulating layer 55 by the use of a lithographic technique or an etching technique. At that time, the contact plugs 54A in the lower layers of the steps DA may be exposed to the outside via the openings 55A.

Next, as illustrated in FIG. 14B, electric conductors are embedded in the openings 55A by a method such as sputtering or CVD to form contact plugs 56A in the openings 55A.

In the foregoing embodiment, the number of stacks in the openings of the same depth is two. Alternatively, the number of stacks in the openings of the same depth may be M (M is an integer of 2 or more).

### Sixth Embodiment

FIG. 15 is a schematic perspective view of a memory cell array in a non-volatile semiconductor storage device according to a sixth embodiment. FIG. 15 illustrates the case where four word lines are stacked and eight it lines are provided.

Referring to FIG. 15, the non-volatile semiconductor storage device is provided with a cell array region RP and a word line extraction region RW adjacent to the cell array region RM. In the cell array region RM, word lines WL1 to WL4 are sequentially stacked in a depth direction DE3 to form a three-dimensional structure. In addition, columnar bodies PS penetrate through the word lines WL1 to WL4 to form memory cells at intersections of the columnar bode PS and the word lines WL1 to WL4. At that time, the columnar bodies PS are aligned two-dimensionally in a row direction DE1 and a column direction DE2 to arrange the memory cells three-dimensionally in the cell array region RM. In the example of FIG. 15, eight memory cells are arranged in the row direction DE1, four memory cells are arranged in the column direction DE2, and four memory cells are arranged in the depth direction DE3. At that time, the word lines WL1 to WL4 can be shared among memory cells in one and the same row or column. A source-side select gate line SGS is provided under the cell array region RM. A drain-side select gate line SGD is provided above the cell array region RM. The drain-side select gate line SGD is separated by row. A source layer B2 is provided under the source-side select gate line SGS. A word line drive circuit B1, a source-side select gate line drive circuit B3, and a drain-side select gate line drive circuit B4 are arranged in parallel to the source layer B2. The word line drive circuit B1, the source layer B2, the source-side select gate line drive circuit B3, and the drain-side select gate line drive circuit B4 may be formed on a semiconductor substrate.

An extraction line W5 is formed above the source-side select gate line SGS. The source-side select gate line SGS is connected to the source-side select gate line drive circuit 83 via the extraction line W5. Bit lines BL0 to BL7 are formed above the drain-side select gate line SGD in the column direction DE2. An extraction line W6 is formed above the drain-side select gate line SGD in the row direction DE1. The drain-side select gate line SGD is connected to the drain-side select gate line drive circuit B4 via the extraction line W6. Extraction lines W1 to W4 are formed above the word line WL4 in correspondence with the word lines WL1 to WL4 in the row direction DE1. The word lines WL1 to WL4 are connected to the word line drive circuit B1 via the extraction lines W1 to W4, respectively.

In the word extraction region RW, steps are provided between the word lines WL1 to WL4. The steps may be formed in the word lines WL1 to WL4 such that upper layers are retracted behind lower layers. The word line WL1 is connected to the extraction line W1 via contact plugs VA1 and VB1. The word line WL2 is connected to the extraction line W2 via contact plugs VA2 and VB2. The word line WL3 is connected to the extraction line W3 via contact plugs VA3 and VB3. The word line WL4 is connected to the extraction line W4 via contact plugs VA4 and VB4. The contact plugs VB1 to VB4 are stacked on the contact plugs VA1 to VA4. The materials for the contact plugs VA1 to VA4 and VB1 to VB4 may be the same or different. The top surfaces of the contact plugs VA1 to VA4 may be larger in area than the bottom surfaces of the contact plugs VB1 to VB4. The contact plugs VA1 to VA4 may be equal or different in length. When the contact plugs VA1 to VA4 are different in length, the contact plugs VA1 to VA4 may be smaller in length in the upper layers than in the lower layers of the word lines WL1 to WL4. The contact plugs VB1 to VB1 may be different in length. The bottom surfaces of the contact plugs VA1 to VA4 may dig into the word lines WL1 to WL4, respectively. At that time, the contact plugs VA1 to VA4 may be equal in depth of digging. The bottom surfaces of the contact plugs VB1 to VB4 may dig into the top surfaces of the contact plugs VA1 to VA4. At that, time, the contact plugs VB1 to VB4 may be larger in depth of digging in the upper layers than in the lower layers of the word lines WL1 to WL4.

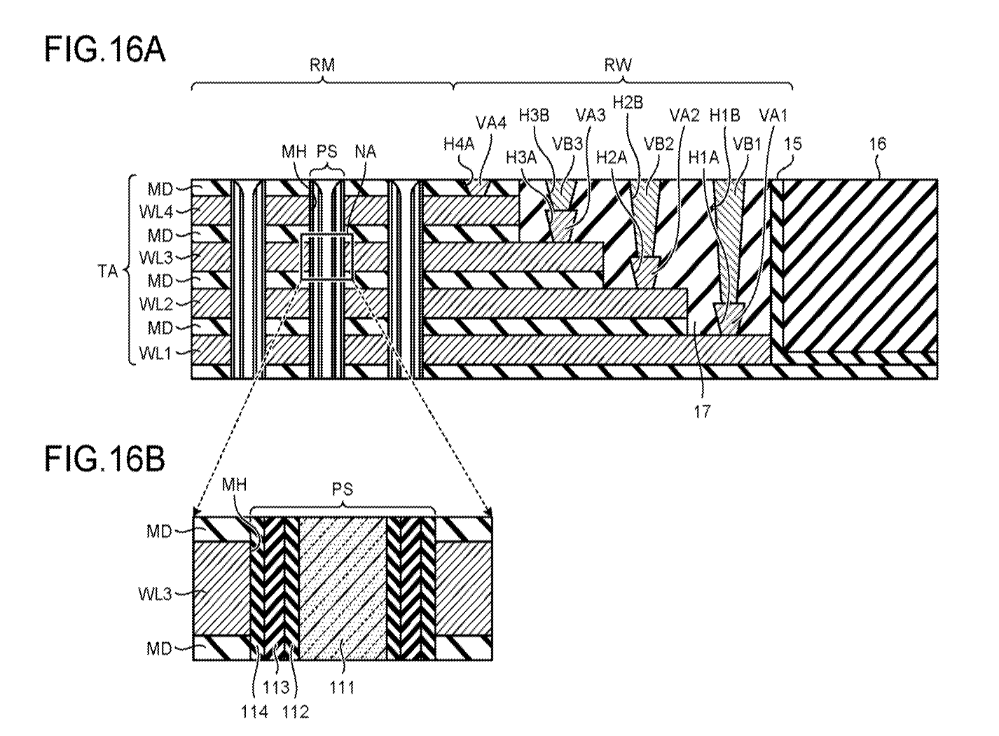

FIG. 16A is a schematic cross-sectional view of the non-volatile semiconductor storage device according to the sixth embodiment, and FIG. 168 is an enlarged cross-sectional view of memory cells illustrated in FIG. 16A.

Referring to FIG. 16A, inter-layer insulating films MD are formed between the word lines WL1 to WL4. The word lines WL1 to WL4 and the inter-layer insulating films MD are alternately stacked in the depth direction DE3 to form the stacked body TA. The materials for the word lines WL1 to WL4 may be an impurity-added polysilicon or a metal such as W. The material for the inter-layer insulating films MD may be a silicon dioxide film, for example. Insulating films 15 and 16 are formed around the stacked body TA.

In the cell array region RM, memory holes MH are formed to penetrate through the word lines WL1 to WL4 in the depth direction DE3. The columnar bodies PS are embedded in the memory holes MH to form memory cells NA at intersections with the word lines WL1 to WL4.

As illustrated in FIG. 168, a columnar semiconductor 111 is formed in the center of the columnar body PS. A tunnel insulating film 112 is formed between the inner surface of the memory hole NH and the columnar semi semiconductor 111, a charge trap layer 113 is formed between the inner surface of the memory hole MH and the tunnel insulating film 112, and a block insulating film 114 is formed between the inner surface of the memory hole MH and the charge trap layer 113. The columnar semiconductor 111 may be a semiconductor such as Si, for example. Insulators may be embedded along a central axis of the columnar semiconductor 111. The tunnel insulating film 112 and the block insulating film 114 may be silicon dioxide films, for example. The charge trap layer 113 may be a silicon nitride film, an ONO film (three-layer structure of silicon dioxide film/silicon nitride film/silicon dioxide film), or an ONOS film (four-layer structure of silicon dioxide film/silicon nitride film/silicon dioxide film/silicon oxynitride film), for example.

In the word line extraction region RW, as illustrated in FIG. 16A, an insulating layer 17 is formed on the word lines WL1 to WL4. The surface of the insulating layer 17 is flattened out. Openings H1A to H4A are formed in the insulating layer 17 to expose the word lines WL1 to WL4 to the outside. Openings H1B to H3B are formed on the openings H1A to H3A. The openings H1A to H3A may be equal in depth. The openings H1B to H3B may be different in depth. Contact plugs VA1 to VA4 are embedded in the openings H1A to H4A. Contact plugs VB1 to VB3 are embedded in the openings H1B to H3B. The top surfaces of the contact plugs VB1 to VB3 may be flush with the surface of the insulating layer 17.

Forming the openings H1B to H3B on the openings H1A to H3A makes it possible to even out over-etching amounts in the word lines WL1 to WL4. Accordingly, it is possible to, when the word lines WL1 to WL4 are thinned, prevent the contact plugs VA1 to VA4 from penetrating through the word lines WL1 to WL4 and prevent a short-circuit to occur between the word lines WL1 to WL4.

FIGS. 15 and 16A illustrate the configuration in which the four word lines are stacked. Alternatively, N (N is an integer of 2 or more) word lines may be stacked. The word line extraction region RW may be configured as illustrated in FIG. 6B, 9B, 11B, 12B, or 14B.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a stacked body of N (N is an integer of 2 or more) layers stacked on a semiconductor substrate;
steps provided in the stacked body such that upper layers are retracted behind lower layers;
N lower openings that are provided in correspondence with the individual layers of the stacked body and are equal in depth;
one to N upper openings that are provided on one to N lower openings and are different in depth;
N lower-layer contact electrodes provided in the lower openings; and
one to N upper-layer contact electrodes provided in the upper openings.

2. The semiconductor device of claim 1, wherein top surfaces of the upper contact electrodes are equal in height.

3. The semiconductor device of claim 1, wherein the lower-layer contact electrodes are shorter in the upper layers than in the lower layers of the stacked body.

4. The semiconductor device of claim 1, wherein
the upper-layer contact electrodes dig into the lower-layer contact electrodes, and
depth of digging is larger in the upper layers than in the lower layers of the stacked body.

5. The semiconductor device of claim 1, wherein
only the lower-layer contact electrodes are provided in contacts on the upper layers of the stacked body, and
the lower-layer contact electrodes and the upper-layer contact electrodes are provided in contacts on the lower layers of the stacked body.

6. The semiconductor device of claim 1, wherein top surfaces of the lower-layer contact electrodes are larger in area than bottom surfaces of the upper-layer contact electrodes.

7. The semiconductor device of claim 1, wherein the lower-layer contact electrodes are stacked only by M (M is an integer of 2 or more) layers.

8. The semiconductor device of claim 1, wherein depth of the lower openings is larger than height of one layer in the stacked body.

9. The semiconductor device of claim 1, wherein
the stacked body includes:
word lines of N layers; and
a columnar body penetrating through the word lines of N layers,
the columnar body includes:
a central body in which a channel is formable;
a tunnel insulating film formed on an outer peripheral surface of the central body;
a charge trap film formed on an outer peripheral surface of the tunnel insulating film; and
a block insulating film formed on an outer peripheral surface of the charge trap film.

10. A semiconductor device, comprising:
a stacked body of N (N is an integer of 2 or more) layers stacked on a semiconductor substrate;
steps provided in the stacked body such that upper layers are retracted behind lower layers;
N openings that are provided in correspondence to the individual layers of the stacked body and are equal in depth; and
N contact electrodes provided in the openings, wherein
over-etching amounts in the individual layers at positions of the openings are equal.

11. A manufacturing method of a semiconductor device, comprising:
forming first openings equal in depth in N (N is an integer of 2 or more) steps of a stepped structure; and
forming second openings different in depth on the first openings.

12. The manufacturing method of a semiconductor device of claim 11, comprising, after the formation of the first openings and the second openings, embedding contact plugs in the first openings and the second openings.

13. The manufacturing method of a semiconductor device of claim 12, wherein
forming the first openings including:
forming a first insulating film uniform in film thickness on the individual steps of the stepped structure; and
forming the first openings by patterning the first insulating film.

14. The manufacturing method of a semiconductor device of claim 13, wherein
forming the second openings including:
embedding a sacrifice film in the first openings;
forming a second insulating film with a top surface flattened out on the sacrifice film; and
forming the second openings by patterning the second insulating film.

15. The manufacturing method of a semiconductor device of claim 14, wherein
after the formation of the second openings, the sacrifice film is removed and then contact plugs are embedded in the first openings and the second openings.

16. The manufacturing method of a semiconductor device of claim 11, comprising:
after the formation of the first openings, embedding first contact plugs in the first openings before the formation of the second openings; and
after the formation of the second openings, embedding second contact plugs in the second openings.

17. The manufacturing method of a semiconductor device of claim 16, wherein
forming the first openings including:
forming a first insulating film uniform in film thickness on the individual steps of the stepped structure; and
forming the first openings by patterning the first insulating film.

18. The manufacturing method of a semiconductor device of claim 17, wherein
forming the second openings including:
embedding the first contact plugs in the first openings;
forming a second insulating film with a top surface flattened out on the first contact plugs; and
forming the second openings by patterning the second insulating film.

19. The manufacturing method of a semiconductor device of claim 18, wherein, after the formation of the second openings, the second contact plugs are embedded in the second openings without removing the first contact plugs.

20. The manufacturing method of a semiconductor device of claim 11, wherein
depths of the first openings are set such that the first openings in the Nth or lower steps protrude from the stepped structure,
a conductive film is embedded in the first openings and then the conductive film is flattened out to form contact plugs equal in height of top surface in the first openings, and
forming the second openings is omitted.
